(19) United States
(12) Patent Application Publication
(10) Pub. No.: US 2024/0057447 A1
(43) Pub. Date: Feb. 15, 2024

(54) OLED DISPLAY PANEL AND OLED DISPLAY DEVICE

(71) Applicant: Shenzhen China Star Optoelectronics Semiconductor Display Technology Co., Ltd., Shenzhen, Guangdong (CN)

(72) Inventors: Wendong LIAN, Shenzhen (CN); Weiran CAO, Shenzhen (CN); Jinchuan LI, Shenzhen (CN); Yang MIAO, Shenzhen (CN)

(21) Appl. No.: 17/621,680

(22) PCT Filed: Dec. 9, 2021
(86) PCT No.: PCT/CN2021/136880

§ 371 Date: Dec. 21, 2021

(30) Foreign Application Priority Data
Nov. 24, 2021 (CN) 202111402542.8

(51) Int. Cl. H10K 59/80

(52) U.S. Cl. CPC H10K 59/873

(57) ABSTRACT

Provided are an OLED display panel and an OLED display device; In the OLED display panel, the filling layer is arranged in the undercut structure, and the filling layer is arranged on the side of the common electrode layer away from the auxiliary electrode layer, such that the filling layer reduces the depth of the undercut structure or fills in the undercut structure to eliminate the level difference of the undercut structure. Then, when the encapsulation layer is formed on the common electrode layer, the fracture of the inorganic layer can be prevented, thereby avoiding the encapsulation failure.

### FIELD OF THE INVENTION

The present application relates to a display technology field, and more particularly to an OLED display panel and an OLED display device.

### BACKGROUND OF THE INVENTION

Organic light-emitting diode (OLED) display devices are widely used due to the advantages of self-luminescence, fast response, ultra-thin and low power consumption. In order to reduce the voltage drop of the current OLED display device, an auxiliary cathode is arranged in the top-emitting OLED display device, and the auxiliary cathode and the transparent cathode are lap jointed to reduce the voltage drop of the cathode layer and improve the display effect. Specifically, the current auxiliary electrode design is to arrange an undercut structure in the OLED display device, so that when the transparent cathode is formed, the transparent cathode can be plated into the laterally etched part, and lap jointed with the auxiliary cathode below, and then an encapsulation layer is formed above, to complete the preparation process of the OLED display device. However, in this process, since the inorganic layer in the encapsulation layer will be formed by chemical vapor deposition, the inorganic layer may be fractured at the undercut, and the fracture of the inorganic layer will cause the encapsulation failure, resulting in water and oxygen intrusion, and the risk is further exacerbated when the OLED display device is bent.

Therefore, the technical problem of encapsulation failure caused by the fracture of the inorganic layer in the encapsulation layer at the undercut exists in the existing OLED display device.

### SUMMARY OF THE INVENTION

The embodiment of the present application provides an OLED display panel and an OLED display device, so as to alleviate the technical problem of encapsulation failure caused by the fracture of the inorganic layer in the encapsulation layer at the undercut of the existing OLED display device.

### Technical Solution

To solve the aforesaid problem, the technical solution of the present application is described as follows:

The embodiment of the present application provides an OLED display panel, comprising:

a substrate;

a driving circuit layer arranged on one side of the substrate;

a light-emitting functional layer arranged on one side of the driving circuit layer away from the substrate, wherein the light-emitting functional layer comprises a common electrode layer and a light-emitting material layer;

a support layer arranged on a side of the light-emitting material layer away from the common electrode layer, wherein the OLED display panel comprises an undercut structure formed in an area where the support layer is arranged;

an auxiliary electrode layer arranged on a side of the support layer away from the common electrode layer, wherein the auxiliary electrode layer and the common electrode layer are connected at the undercut structure;

an encapsulation layer arranged on a side of the light emitting functional layer away from the driving circuit layer:

wherein the OLED display panel further comprises a filling layer disposed in the undercut structure, and in the undercut structure, the filling layer is disposed on a side of the common electrode layer away from the auxiliary electrode layer.

In some embodiments, the common electrode layer comprises a via hole formed in an area corresponding to the undercut structure, and the filling layer extends from the undercut structure to the via hole.

In some embodiments, at the via hole, the filling layer is in contact with the common electrode layers on both sides, and a surface of the filling layer on a side away from the auxiliary electrode layer has a same height as a surface of the common electrode layers on both sides of the via hole.

In some embodiments, the filling layer extends from the undercut structure to an outside of the via hole, and outside the via hole of the common electrode layer, the filling layer is disposed between the common electrode layer and the encapsulation layer.

In some embodiments, the filling layer comprises a first filling layer and a second filling layer, and the first filling layer is disposed between the second filling layer and the common electrode layer.

In some embodiments, a material of the first filling layer is a conductive material, and a material of the second filling layer is a non-conductive material, and the second filling layer covers the first filling layer in the undercut structure.

In some embodiments, a thickness of the second filling layer is greater than a thickness of the first filling layer.

In some embodiments, the filling layer further comprises a third filling layer disposed between the first filling layer and the second filling layer, and a contact angle between the third filling layer and the second filling layer is smaller than a contact angle between the third filling layer and the first filling layer.

In some embodiments, the auxiliary electrode layer comprises an auxiliary electrode, and the driving circuit layer comprises a source and drain layer, and the auxiliary electrode is disposed in the source and drain layer.

Meanwhile, the embodiment of the present application provides an OLED display device, comprising:

an OLED display panel comprising a substrate, a driving circuit layer, a light-emitting functional layer, a support layer, an auxiliary electrode layer and an encapsulation layer, wherein the driving circuit layer is arranged on a side of the substrate, and the light-emitting functional layer is arranged on one side of the driving circuit layer away from the substrate, and the light-emitting functional layer comprises a common electrode layer and a light-emitting material layer, and the support layer is arranged on a side of the light-emitting material layer away from the common electrode layer, and the OLED display panel comprises an undercut structure formed in an area where the support layer is arranged, and the auxiliary electrode layer is arranged on a side of the support layer away from the common electrode layer, and the auxiliary electrode layer and the common electrode layer are connected at the undercut structure, and the encapsulation layer is arranged on a side of the light emitting functional layer away from the driving circuit layer, wherein the OLED display panel further comprises a filling layer disposed in the undercut structure, and in the undercut structure, the filling layer is disposed on a side of the common electrode layer away from the auxiliary electrode layer;

an electronic component arranged on a side of the OLED display panel.

In some embodiments, the common electrode layer comprises a via hole formed in an area corresponding to the undercut structure, and the filling layer extends from the undercut structure to the via hole.

In some embodiments, at the via hole, the filling layer is in contact with the common electrode layers on both sides, and a surface of the filling layer on a side away from the auxiliary electrode layer has a same height as a surface of the common electrode layers on both sides of the via hole.

In some embodiments, the filling layer extends from the undercut structure to an outside of the via hole, and outside the via hole of the common electrode layer, the filling layer is disposed between the common electrode layer and the encapsulation layer.

In some embodiments, the filling layer comprises a first filling layer and a second filling layer, and the first filling layer is disposed between the second filling layer and the common electrode layer.

In some embodiments, a material of the first filling layer is a conductive material, and a material of the second filling layer is a non-conductive material, and the second filling layer covers the first filling layer in the undercut structure.

In some embodiments, a thickness of the second filling layer is greater than a thickness of the first filling layer.

In some embodiments, the filling layer further comprises a third filling layer disposed between the first filling layer and the second filling layer, and a contact angle between the third filling layer and the second filling layer is smaller than a contact angle between the third filling layer and the first filling layer.

In some embodiments, the auxiliary electrode layer comprises an auxiliary electrode, and the driving circuit layer comprises a source and drain layer, and the auxiliary electrode is disposed in the source and drain layer.

In some embodiments, the support layer comprises a support unit, and the light-emitting functional layer comprises a pixel electrode layer, and the support unit is disposed in the pixel electrode layer.

In some embodiments, the driving circuit layer comprises a planarization layer and a passivation layer, and the auxiliary electrode layer is disposed between the planarization layer and the passivation layer.

The present application provides an OLED display panel and an OLED display device; the OLED display panel comprises a substrate, a driving circuit layer, a light-emitting functional layer, a support layer, an auxiliary electrode layer and an encapsulation layer, and the driving circuit layer is arranged on a side of the substrate, and the light-emitting functional layer is arranged on one side of the driving circuit layer away from the substrate, and the light-emitting functional layer comprises a common electrode layer and a light-emitting material layer, and the support layer is arranged on a side of the light-emitting material layer away from the common electrode layer, and the OLED display panel comprises an undercut structure formed in an area where the support layer is arranged, and the auxiliary electrode layer is arranged on a side of the support layer away from the common electrode layer, and the auxiliary electrode layer and the common electrode layer are connected at the undercut structure, and the encapsulation layer is arranged on a side of the light emitting functional layer away from the driving circuit layer, wherein the OLED display panel further comprises a filling layer disposed in the undercut structure, and in the undercut structure, the filling layer is disposed on a side of the common electrode layer away from the auxiliary electrode layer. In this application, the filling layer is arranged in the undercut structure, and the filling layer is arranged on the side of the common electrode layer away from the auxiliary electrode layer, such that the filling layer reduces the depth of the undercut structure or fills in the undercut structure to eliminate the level difference of the undercut structure. Then, when the encapsulation layer is formed on the common electrode layer, the depth of the contact area of the inorganic layer in the encapsulation layer is relatively low or relatively flat, so as to prevent the fracture of the inorganic layer, thereby avoiding the encapsulation failure.

### BRIEF DESCRIPTION OF THE DRAWINGS

The technical solution and the beneficial effects of the present application are best understood from the following detailed description with reference to the accompanying figures and embodiments.

FIG. 1 is a first diagram of an OLED display panel provided by an embodiment of the application.

FIG. 2 is a second diagram of an OLED display panel provided by an embodiment of the application.

FIG. 3 is a third diagram of an OLED display panel provided by an embodiment of the application.

FIG. 4 is a diagram of an OLED display device provided by an embodiment of the application.

### DETAILED DESCRIPTION OF PREFERRED EMBODIMENTS

For better explaining the technical solution and the effect of the present invention, the present invention will be further described in detail with the accompanying drawings in the specific embodiments. It is clear that the described embodiments are merely part of embodiments of the present application, but not all embodiments. Based on the embodiments of the present application, all other embodiments to those of skilled in the premise of no creative efforts obtained, should be considered within the scope of protection of the present application.

In view of the technical problem of the encapsulation failure caused by the fracture of the inorganic layer in the encapsulation layer at the undercut of the existing OLED display device, the embodiments of the present application provide an OLED display panel and an OLED display device to alleviate the aforesaid technical problems.

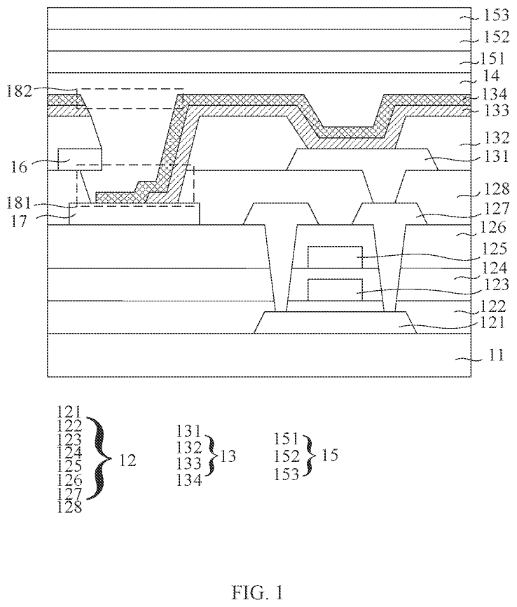

As shown in FIG. 1, the embodiment of the present application provides an OLED display panel. The OLED display panel comprises:

a substrate 11;

a driving circuit layer 12 arranged on one side of the substrate 11;

a light-emitting functional layer 13 arranged on one side of the driving circuit layer 12 away from the substrate 11, wherein the light-emitting functional layer 13 comprises a common electrode layer 134 and a light-emitting material layer 133;

a support layer 16 arranged on a side of the light-emitting material layer 133 away from the common electrode layer 134, wherein the OLED display panel comprises an undercut structure 181 formed in an area where the support layer 16 is arranged;

an auxiliary electrode layer 17 arranged on a side of the support layer 16 away from the common electrode layer 134, wherein the auxiliary electrode layer 17 and the common electrode layer 134 are connected at the undercut structure 181;

an encapsulation layer 15 arranged on one side of the light emitting functional layer 13 away from the driving circuit layer 12;

wherein the OLED display panel further comprises a filling layer 14, and the filling layer 14 is disposed in the undercut structure 181, and in the undercut structure 181, the filling layer 14 is disposed on a side of the common electrode layer 134 away from the auxiliary electrode layer 17.

The embodiment of the present application provides an OLED display panel. In the OLED display panel, the filling layer is arranged in the undercut structure, and the filling layer is arranged on the side of the common electrode layer away from the auxiliary electrode layer, such that the filling layer reduces the depth of the undercut structure or fills in the undercut structure to eliminate the level difference of the undercut structure. Then, when the encapsulation layer is formed on the common electrode layer, the depth of the contact area of the inorganic layer in the encapsulation layer is relatively low or relatively flat, so as to prevent the fracture of the inorganic layer, thereby avoiding the encapsulation failure.

In one embodiment, the height of the filling layer in the undercut structure is equal to the height of the supporting layer. When the filling layer is disposed, the filling layer can be arranged in the undercut structure, by filling the undercut structure to be flush with the support layer, only the via hole formed by the film layer on the support layer exist in the area corresponding to the undercut structure. The depth of these via holes is small, so that even if these via holes are not filled, when the inorganic layer of the encapsulation layer is formed, the level difference of the undercut structure is eliminated, and the height difference of the inorganic layer in different areas is small, thus the inorganic layer is less likely to be fractured or even not fractured, thereby reducing the possibility of failure of the encapsulation layer.

Specifically, when the filling layer is arranged in the undercut structure, the filling layer is arranged in respective undercut structures, so that the filling layer is respectively arranged in a plurality of undercut structures The undercut structure is filled up, thereby avoiding the fracture of the inorganic layer and avoiding the encapsulation failure of the OLED display panel.

In one embodiment, the common electrode layer comprises a via hole formed in an area corresponding to the undercut structure, and the filling layer extends from the undercut structure to the via hole. By extending the undercut structure to the via hole of the common electrode layer, in addition to filling the undercut structure, the filling layer can also fill the via hole in the corresponding area of the undercut structure. Therefore, in the area corresponding to the undercut structure, there is only partial via or even no via, which reduces the depth of the via hole at the undercut. Thus, the height difference when the inorganic layer is formed in the encapsulation layer is reduced, the risk of the fracture of the inorganic layer is reduced, and the encapsulation result of the OLED display panel is improved.

Specifically, in the area corresponding to the undercut structure, there will be the via hole formed by the undercut structure and the via holes formed by the film layers on the support layer, such as the via formed by the pixel definition layer and the via formed by the common electrode layer. Then, the filling layer can be made to extend upward from the common electrode layer at the bottom of the undercut structure, so that the filling layer is filled in the undercut structure and the via holes in the film layers, thereby reducing the height difference between the undercut structure and other positions. When the inorganic layer in the encapsulation layer is formed, the height difference between different areas of the inorganic layer is reduced, so as to avoid encapsulation failure and improve the encapsulation result of the OLED display panel.

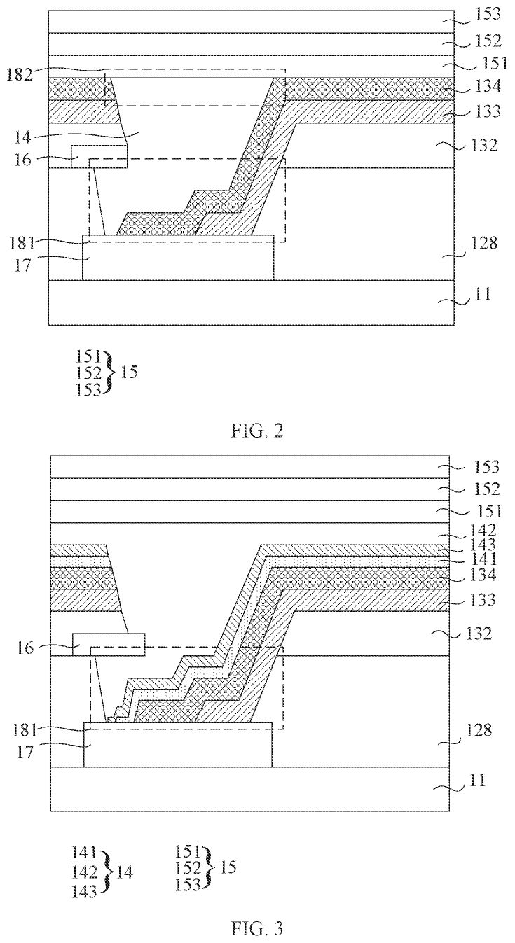

In one embodiment, as shown in FIG. 2, at the via hole 182, the filling layer 14 is in contact with the common electrode layers 134 on both sides, and a surface of the filling layer 14 on a side away from the auxiliary electrode layer 17 has the same height as a surface of the common electrode layers 134 on both sides of the via hole 182. By extending the filling layer from the undercut structure to the via hole of the common electrode layer at the undercut structure to make the upper surface of the filling layer flush with the upper surface of the common electrode layer, the filling layer fills the via holes at the corresponding position of the undercut structure, so that the inorganic layer in the encapsulation layer can be directly formed on the planar surface. The inorganic layer will not form an uneven structure at the corresponding position of the undercut structure, thereby eliminating the height difference of the inorganic layer, reducing the fracture risk of the inorganic layer, and improving the encapsulation result of the OLED display panel. Moreover, During the disposing process of the filling layer, since the filling layer is arranged at the undercut structure and the via hole, it will not exceed the common electrode layer and will not increase the thickness of the OLED display panel.

Specifically, as shown in FIG. 2, in the area corresponding to the undercut structure 181, there will be a via hole of the undercut structure 181, a via hole of the pixel definition layer 132, a via hole of the light-emitting material layer 133 and a via hole of the common electrode layer 134. The superposition of multiple via holes will cause the depth of the holes in the corresponding area of the undercut structure to be larger. When the inorganic layer is formed, the inorganic layer will be fractured here, and the presence of the undercut structure will cause the inorganic layer to fail to be connected here. In the embodiment of the present application, by filling the undercut structure and the via holes, the filling layer can specifically fill the undercut structure and the via holes of all film layers to eliminate the via holes.

Specifically, the filling layers are respectively arranged in multiple undercut structures. When the multiple undercut structures are formed in the OLED display panel to reduce the voltage drop of the common electrode layer, the filling layers are respectively arranged in the multiple undercut structures, so that the respective filling layers fill are separated but filled into the respective undercut structures. Thus, the filling layer is not arranged on the common electrode layer in other areas, and does not increase the thickness of the OLED display panel, and avoids the problem of the inorganic layer in the encapsulation layer being fractured by the level difference at the undercut structure.

For other areas outside the undercut structure of the OLED display panel, a via hole or a level difference may also exist, which may cause the problem of possible fracture of the inorganic layer. In one embodiment, as shown in FIG. 1, the filling layer 14 extends from the undercut structure 181 to the outside of the via hole 182, and outside the via hole 182 of the common electrode layer 134, the filling layer 14 is disposed between the common electrode layer 134 and the encapsulation layer 15. By filling the filling layer into the undercut structure and extending the filling layer to the common electrode layer, the filling layer fills in the via holes or the level differences formed in other areas of the OLED display panel. When the inorganic layer is formed, all areas of the OLED display panel are planar, so as the inorganic layer is formed, no via holes or level differences will be encountered, and there will be no fractures caused by the via holes and level differences, which improves the encapsulation result of the OLED display panel.

Specifically, when the filling layer is formed, the filling layer is formed on the entire surface, so that the filling layer is filled in the undercut structure for all undercut structures and extends to the outside of the via holes. Thus, the height of the filling layer on the surface of each area of the OLED display panel is consistent, and the filling layer fills up all undercut structures in the OLED display panel.

In one embodiment, as shown in FIG. 3, the filling layer 14 comprises a first filling layer 141 and a second filling layer 142, and the first filling layer 141 is disposed between the second filling layer 142 and the common electrode layer 134. By dividing the filling layer into the first filling layer and the second filling layer, when the first filling layer and the second filling layer fill the undercut structure and the via hole, the first filling layer and the second filling layer can complement each other, and fill in the undercut structure and the via hole, to avoid the fracture during the formation of the inorganic layer, and to improve the encapsulation result of the OLED display panel.

In one embodiment, as shown in FIG. 3, a material of the first filling layer 141 is a conductive material, and a material of the second filling layer 142 is a non-conductive material, and the second filling layer 142 covers the first filling layer 141 in the undercut structure 181. Since the material of the first filling layer is a conductive material, and the material of the second filling layer is a non-conductive material, the first filling layer can further reduce the voltage drop of the common electrode layer, and the first filling layer can prevent the second filling layer from contacting the common electrode layer, and when the second filling layer is invaded by water and oxygen, it prevents water and oxygen from intruding into the common electrode layer. The second filling layer can fill up the undercut structure and the via hole, thereby avoiding the problem of the fracture of the inorganic layer in the encapsulation layer caused by the level difference at the undercut structure, and improving the encapsulation result of the OLED display panel.

Specifically, the material of the first filling layer comprises indium zinc oxide.

Specifically, the material of the second filling layer is an organic material. Since the organic material possesses good flexibility, the organic material can be formed by inkjet printing or other liquid solidification methods to form the organic layer. The fluidity of the liquid is utilized to flow the liquid into the undercut structure and into the via hole. The undercut structure and the via hole can be filled to avoid the level difference or the height difference between the undercut structure and the via hole causing the fracture as forming the inorganic layer. Moreover, since the second filling layer is made of organic material, the flexibility of the OLED display panel can be further improved.

Specifically, as shown in FIG. 3, the first filling layer 141 may be fractured at the undercut structure 181, the first filling layer 141 covers the common electrode layer 134 to prevent the second filling layer 142 from directly contacting the common electrode layer, thereby preventing water, oxygen or other substances existing in the second filling layer from invading the light-emitting material layer through the common electrode layer, resulting in light-emitting failure. For instance, when the organic layer is formed, there will be organic components such as solvents, photoinitiators, leveling agents and gases that exist after the organic layer is cured. When the organic layer is in direct contact with the common electrode layer, it will cause organic components and gases to invade from the common electrode layer to the light-emitting material layer, resulting in the failure of the light-emitting material and thus the failure of the OLED display panel; when water and oxygen invade from the side of the second filling layer, due to the barrier of the first filling layer, the water and oxygen can only invade the second filling layer, but not into the light-emitting material layer, thereby improving the encapsulation result.

In one embodiment, a thickness of the second filling layer is greater than a thickness of the first filling layer. By making the thickness of the second filling layer greater than the thickness of the first filling layer, and the first filling layer is disposed on the second filling layer in the undercut structure, the thickness of the first filling layer will not be thicker. Since the length of the light-emitting cavity in the OLED display panel is determined by the distance between the two electrodes, and the first filling layer is made of conductive material, the cavity length of each pixel of the OLED display panel will be affected when the thickness is too thick, resulting in that the display effect of the OLED display panel is different from the preset display effect. Therefore, while blocking the second filling layer and the common electrode layer by the first filling layer, the thickness of the second filling layer is made to be greater than the thickness of the second filling layer, thereby avoiding the influence of the first filling layer to the cavity length of the light-emitting pixels of the OLED display panel.

Specifically, the thickness of the first filling layer is less than 50 nanometers. By reducing the thickness of the first filling layer, it is avoided that the first filling layer affects the light-emitting cavity length of the light-emitting pixels of the OLED display panel.

In one embodiment, as shown in FIG. 3, the filling layer 14 further comprises a third filling layer 143. The third filling layer 143 is disposed between the first filling layer 141 and the second filling layer 142, and a contact angle between the third filling layer 143 and the second filling layer 142 is smaller than a contact angle between the third filling layer 143 and the first filling layer 141. By arranging the third filling layer, the third filling layer is arranged between the first filling layer and the second filling layer, and the contact angle between the third filling layer and the second filling layer is smaller than the contact angle between the third filling layer and the first filling layer. When the second filling layer is formed, the second filling layer can be leveled quickly, and the problem of unevenness of the second filling layer can be avoided.

Specifically, the material of the third filling layer comprises inorganic materials. Since the third filling layer is formed by inorganic materials, when the second filling layer is formed, the contact angle between the liquid corresponding to the second filling layer and the third filling layer is smaller, which speeds up the leveling of the liquid corresponding to the second filling layer, and speeds up the productivity of the OLED display panel; meanwhile, the third filling layer is arranged between the first filling layer and the second filling layer to further prevent the second filling layer from contacting the common electrode layer, and the third filling layer is made of inorganic materials, which can improve the capacity of the OLED display panel to block the water and oxygen.

In one embodiment, as shown in FIG. 1, the auxiliary electrode layer 17 comprises an auxiliary electrode, and the driving circuit layer 12 comprises a source and drain layer 127, and the auxiliary electrode is disposed in the source and drain layer 127. By arranging the auxiliary electrode on the source and drain layer, there is no need to additionally provide an auxiliary electrode layer, thereby reducing the thickness of the OLED display panel.

Specifically, the OLED display panel comprises an active area and a non-active area, the undercut structure is disposed in the non-active area, and the auxiliary electrode is disposed in the non-active area. Since the undercut structure is arranged in the non-active area, when the auxiliary electrode layer is formed, the auxiliary electrode can be formed by designing the source and drain layer, and the auxiliary electrode does not occupy the position of the source and drain layer in the active area. The arrangement does not need to increase the process, and reduces the thickness of the OLED display panel.

The aforesaid embodiment is described in detail by taking the auxiliary electrode disposed in the source and drain layer as an illustration. However, the embodiment of the present application is not limited to this, and the auxiliary electrode may be disposed in other film layers. For instance, in order to reduce the depth of the via hole, the auxiliary electrode layer may be provided on the source and drain layer.

In one embodiment, the driving circuit layer comprises a planarization layer, and the auxiliary electrode layer is disposed under the passivation layer. By disposing the auxiliary electrode layer under the passivation layer, the depth of the via hole at the undercut structure is reduced.

In one embodiment, as shown in FIG. 1, the support layer 16 comprises a support unit, and the light-emitting functional layer 13 comprises a pixel electrode layer 131, and the support unit is disposed in the pixel electrode layer 131. By arranging the support unit in the pixel electrode layer, there is no need to additionally provide a support layer, which reduces the thickness of the OLED display panel.

The aforesaid embodiment is described in detail by taking the support layer arranged in the pixel electrode layer as an illustration. However, the embodiment of the present application is not limited to this. For instance, the support layer may be disposed under the pixel electrode layer.

In one embodiment, as shown in FIG. 1, the driving circuit layer 12 comprises an active layer 121, a first gate insulating layer 122, a first metal layer 123, a second gate insulating layer 124, a second metal layer 125, an interlayer insulating layer 126, a source and drain layer 127 and a planarization layer 128.

In one embodiment, the light-emitting material layer comprises a hole injection layer, a hole transport layer, an electron transport layer and an electron injection layer.

In one embodiment, the electron transport layer is provided on the entire surface, and the hole injection layer and the hole transport layer are provided in the pixel area defined by the pixel definition layer.

In one embodiment, as shown in FIG. 1, the encapsulation layer 15 comprises a first inorganic layer 151, an organic layer 152 and a second inorganic layer 153.

Meanwhile, the embodiment of the present application provides a manufacturing method of an OLED display panel. The manufacturing method of the OLED display panel comprises:

providing a substrate;

forming a driving circuit layer on the substrate; the driving circuit layer comprises a source and drain layer and a planarization layer, and the source and drain layer comprises an auxiliary electrode layer;

forming a pixel electrode layer on the driving circuit layer; the pixel electrode layer comprises a support layer;

forming a pixel definition layer on the pixel electrode layer, and etching the pixel definition layer to form a pixel area;

etching the pixel definition layer and the planarization layer to form an undercut structure;

forming a light-emitting material layer on the pixel definition layer;

forming a common electrode layer on the light-emitting material layer; the auxiliary electrode layer and the common electrode layer are connected at the undercut structure;

forming a filling layer on the common electrode layer; the filling layer is filled in the undercut structure;

forming an encapsulation layer on the filling layer.

The embodiment of the present application provides a manufacturing method of an OLED display panel. In the OLED display panel manufactured by the manufacturing method of the OLED display panel, the filling layer is arranged in the undercut structure, and the filling layer is arranged on the side of the common electrode layer away from the auxiliary electrode layer, such that the filling layer reduces the depth of the undercut structure or fills in the undercut structure to eliminate the level difference of the undercut structure. Then, when the encapsulation layer is formed on the common electrode layer, the depth of the contact area of the inorganic layer in the encapsulation layer is relatively low or relatively flat, so as to prevent the fracture of the inorganic layer, thereby avoiding the encapsulation failure.

In one embodiment, the step of forming filling layer on the common electrode layer comprises:

forming a first filling layer by sputtering coating on the common electrode layer; a material of the first filling layer comprises a conductive material;

forming a third filling layer on the first filling layer by chemical vapor deposition; a material of the third filling layer comprises an inorganic material;

forming a second filling layer on the third filling layer by inkjet printing; a material of the second filling layer comprises an organic material.

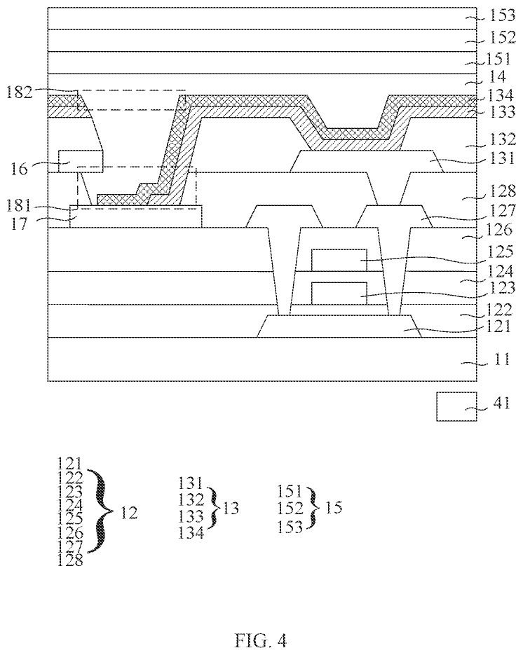

Meanwhile, as shown in FIG. 4, the embodiment of the present application provides an OLED display device. The OLED display device comprises:

an OLED display panel, comprising a substrate 11, a driving circuit layer 12, a light-emitting functional layer 13, a support layer 16, an auxiliary electrode layer 17 and an encapsulation layer 15, wherein the driving circuit layer 12 is arranged on a side of the substrate 11, and the light-emitting functional layer 13 is arranged on one side of the driving circuit layer 12 away from the substrate 11, and the light-emitting functional layer 13 comprises a common electrode layer 134 and a light-emitting material layer 133, and the support layer 16 is arranged on a side of the light-emitting material layer 133 away from the common electrode layer 134, and the OLED display panel comprises an undercut structure 181 formed in an area where the support layer 16 is arranged, and the auxiliary electrode layer 17 is arranged on a side of the support layer 16 away from the common electrode layer 134, and the auxiliary electrode layer 17 and the common electrode layer 134 are connected at the undercut structure 181, and the encapsulation layer 15 is arranged on one side of the light emitting functional layer 13 away from the driving circuit layer 12, wherein the OLED display panel further comprises a filling layer 14, and the filling layer 14 is disposed in the undercut structure 181, and in the undercut structure 181, the filling layer 14 is disposed on a side of the common electrode layer 134 away from the auxiliary electrode layer 17;

an electronic component 41 arranged on a side of the OLED display panel.

The embodiment of the present application provides an OLED display device. The OLED display device comprises an OLED display panel and electronic component. In the OLED display panel, the filling layer is arranged in the undercut structure, and the filling layer is arranged on the side of the common electrode layer away from the auxiliary electrode layer, such that the filling layer reduces the depth of the undercut structure or fills in the undercut structure to eliminate the level difference of the undercut structure. Then, when the encapsulation layer is formed on the common electrode layer, the depth of the contact area of the inorganic layer in the encapsulation layer is relatively low or relatively flat, so as to prevent the fracture of the inorganic layer, thereby avoiding the encapsulation failure.

In one embodiment, in the OLED display device, the common electrode layer comprises a via hole formed in an area corresponding to the undercut structure, and the filling layer extends from the undercut structure to the via hole.

In one embodiment, in the OLED display device, at the via hole, the filling layer is in contact with the common electrode layers on both sides, and a surface of the filling layer on a side away from the auxiliary electrode layer has a same height as a surface of the common electrode layers on both sides of the via hole.

In one embodiment, in the OLED display device, the filling layer extends from the undercut structure to an outside of the via hole, and outside the via hole of the common electrode layer, the filling layer is disposed between the common electrode layer and the encapsulation layer.

In one embodiment, in the OLED display device, the filling layer comprises a first filling layer and a second filling layer, and the first filling layer is disposed between the second filling layer and the common electrode layer.

In one embodiment, in the OLED display device, a material of the first filling layer is a conductive material, and a material of the second filling layer is a non-conductive material, and the second filling layer covers the first filling layer in the undercut structure.

In one embodiment, in the OLED display device, a thickness of the second filling layer is greater than a thickness of the first filling layer.

In one embodiment, in the OLED display device, the filling layer further comprises a third filling layer disposed between the first filling layer and the second filling layer, and a contact angle between the third filling layer and the second filling layer is smaller than a contact angle between the third filling layer and the first filling layer.

In one embodiment, in the OLED display device, the auxiliary electrode layer comprises an auxiliary electrode, and the driving circuit layer comprises a source and drain layer, and the auxiliary electrode is disposed in the source and drain layer.

In one embodiment, in the OLED display device, the support layer comprises a support unit, and the light-emitting functional layer comprises a pixel electrode layer, and the support unit is disposed in the pixel electrode layer.

In one embodiment, in the OLED display device, the driving circuit layer comprises a planarization layer and a passivation layer, and the auxiliary electrode layer is disposed between the planarization layer and the passivation layer.

It can be known according to the aforesaid embodiment:

The embodiment of the present application provides an OLED display panel and an OLED display device; the OLED display panel comprises a substrate, a driving circuit layer, a light-emitting functional layer, a support layer, an auxiliary electrode layer and an encapsulation layer, and the driving circuit layer is arranged on a side of the substrate, and the light-emitting functional layer is arranged on one side of the driving circuit layer away from the substrate, and the light-emitting functional layer comprises a common electrode layer and a light-emitting material layer, and the support layer is arranged on a side of the light-emitting material layer away from the common electrode layer, and the OLED display panel comprises an undercut structure formed in an area where the support layer is arranged, and the auxiliary electrode layer is arranged on a side of the support layer away from the common electrode layer, and the auxiliary electrode layer and the common electrode layer are connected at the undercut structure, and the encapsulation layer is arranged on a side of the light emitting functional layer away from the driving circuit layer, wherein the OLED display panel further comprises a filling layer disposed in the undercut structure, and in the undercut structure, the filling layer is disposed on a side of the common electrode layer away from the auxiliary electrode layer. In this application, the filling layer is arranged in the undercut structure, and the filling layer is arranged on the side of the common electrode layer away from the auxiliary electrode layer, such that the filling layer reduces the depth of the undercut structure or fills in the undercut structure to eliminate the level difference of the undercut structure. Then, when the encapsulation layer is formed on the common electrode layer, the depth of the contact area of the inorganic layer in the encapsulation layer is relatively low or relatively flat, so as to prevent the fracture of the inorganic layer, thereby avoiding the encapsulation failure.

In the foregoing embodiments, the description of the various embodiments have respective different emphases, and a part in some embodiment, which is not described in detail can be referred to the related description of other embodiments.

The OLED display panel and the OLED display device provided by the embodiments of the present application is described in detail as aforementioned, and the principles and implementations of the present application have been described with reference to specific illustrations. The description of the foregoing embodiments is merely for helping to understand the technical solutions of the present application and the core ideas thereof: those skilled in the art should understand that the technical solutions described in the foregoing embodiments may be modified, or some of the technical features may be equivalently replaced; and the modifications or replacements do not deviate from the spirit and scope of the technical solutions of the embodiments of the present application.

What is claimed is:

1. An organic light emitting diode (OLED) display panel, comprising:
a substrate;
a driving circuit layer arranged on one side of the substrate;
a light-emitting functional layer arranged on one side of the driving circuit layer away from the substrate, wherein the light-emitting functional layer comprises a common electrode layer and a light-emitting material layer;
a support layer arranged on a side of the light-emitting material layer away from the common electrode layer, wherein the OLED display panel comprises an undercut structure formed in an area where the support layer is arranged;
an auxiliary electrode layer arranged on a side of the support layer away from the common electrode layer, wherein the auxiliary electrode layer and the common electrode layer are connected at the undercut structure;
an encapsulation layer arranged on a side of the light emitting functional layer away from the driving circuit layer;
wherein the OLED display panel further comprises a filling layer disposed in the undercut structure, and in the undercut structure, the filling layer is disposed on a side of the common electrode layer away from the auxiliary electrode layer.

2. The OLED display panel according to claim 1, wherein the common electrode layer comprises a via hole formed in an area corresponding to the undercut structure, and the filling layer extends from the undercut structure to the via hole.

3. The OLED display panel according to claim 2, wherein at the via hole, the filling layer is in contact with the common electrode layers on both sides, and a surface of the filling layer on a side away from the auxiliary electrode layer has a same height as a surface of the common electrode layers on both sides of the via hole.

4. The OLED display panel according to claim 2, wherein the filling layer extends from the undercut structure to an outside of the via hole, and outside the via hole of the common electrode layer, the filling layer is disposed between the common electrode layer and the encapsulation layer.

5. The OLED display panel according to claim 4, wherein the filling layer comprises a first filling layer and a second filling layer, and the first filling layer is disposed between the second filling layer and the common electrode layer.

6. The OLED display panel according to claim 5, wherein a material of the first filling layer is a conductive material, and a material of the second filling layer is a non-conductive material, and the second filling layer covers the first filling layer in the undercut structure.

7. The OLED display panel according to claim 6, wherein a thickness of the second filling layer is greater than a thickness of the first filling layer.

8. The OLED display panel according to claim 5, wherein the filling layer further comprises a third filling layer disposed between the first filling layer and the second filling layer, and a contact angle between the third filling layer and the second filling layer is smaller than a contact angle between the third filling layer and the first filling layer.

9. The OLED display panel according to claim 1, wherein the auxiliary electrode layer comprises an auxiliary electrode, and the driving circuit layer comprises a source and drain layer, and the auxiliary electrode is disposed in the source and drain layer.

10. An OLED display device, comprising:
an OLED display panel comprising a substrate, a driving circuit layer, a light-emitting functional layer, a support layer, an auxiliary electrode layer and an encapsulation layer, wherein the driving circuit layer is arranged on a side of the substrate, and the light-emitting functional layer is arranged on one side of the driving circuit layer away from the substrate, and the light-emitting functional layer comprises a common electrode layer and a light-emitting material layer, and the support layer is arranged on a side of the light-emitting material layer away from the common electrode layer, and the OLED display panel comprises an undercut structure formed in an area where the support layer is arranged, and the auxiliary electrode layer is arranged on a side of the support layer away from the common electrode layer, and the auxiliary electrode layer and the common electrode layer are connected at the undercut structure, and the encapsulation layer is arranged on a side of the light emitting functional layer away from the driving circuit layer, wherein the OLED display panel further comprises a filling layer disposed in the undercut structure, and in the undercut structure, the filling layer is disposed on a side of the common electrode layer away from the auxiliary electrode layer;
an electronic component arranged on a side of the OLED display panel.

11. The OLED display device according to claim 10, wherein the common electrode layer comprises a via hole formed in an area corresponding to the undercut structure, and the filling layer extends from the undercut structure to the via hole.

12. The OLED display device according to claim 11, wherein at the via hole, the filling layer is in contact with the common electrode layers on both sides, and a surface of the filling layer on a side away from the auxiliary electrode layer has a same height as a surface of the common electrode layers on both sides of the via hole.

13. The OLED display device according to claim 11, wherein the filling layer extends from the undercut structure to an outside of the via hole, and outside the via hole of the common electrode layer, the filling layer is disposed between the common electrode layer and the encapsulation layer.

14. The OLED display device according to claim 13, wherein the filling layer comprises a first filling layer and a second filling layer, and the first filling layer is disposed between the second filling layer and the common electrode layer.

15. The OLED display device according to claim 14, wherein a material of the first filling layer is a conductive material, and a material of the second filling layer is a non-conductive material, and the second filling layer covers the first filling layer in the undercut structure.

16. The OLED display device according to claim 15, wherein a thickness of the second filling layer is greater than a thickness of the first filling layer.

17. The OLED display device according to claim 14, wherein the filling layer further comprises a third filling layer disposed between the first filling layer and the second filling layer, and a contact angle between the third filling layer and the second filling layer is smaller than a contact angle between the third filling layer and the first filling layer.

18. The OLED display device according to claim 10, wherein the auxiliary electrode layer comprises an auxiliary electrode, and the driving circuit layer comprises a source and drain layer, and the auxiliary electrode is disposed in the source and drain layer.

19. The OLED display device according to claim 10, wherein the support layer comprises a support unit, and the light-emitting functional layer comprises a pixel electrode layer, and the support unit is disposed in the pixel electrode layer.

20. The OLED display device according to claim 10, wherein the driving circuit layer comprises a planarization layer and a passivation layer, and the auxiliary electrode layer is disposed between the planarization layer and the passivation layer.
